(19) United States
(12) Patent Application Publication
(10) Pub. No.: US 2009/0267122 A1
(43) Pub. Date: Oct. 29, 2009

(54) Semiconductor device and method of manufacturing the semiconductor device

(75) Inventors: Tadahiro Ohmi, Miyagi (JP); Ichiro Takahashi, Miyagi (JP)

Correspondence Address: FOLEY AND LARDNER LLP;SUITE 500, 3000 K STREET NW, WASHINGTON, DC, 20007, US

(73) Assignees: National University Corporation Tohoku University; Foundation for Advancement of International Science

(21) Appl. No.: 12/385,868

(22) Filed: Apr. 22, 2009

(30) Foreign Application Priority Data
Apr. 23, 2008 (JP) 2008-112994

(51) Int. Cl. H01L 29/51; H01L 21/28

(52) U.S. Cl. 257/295; 438/3; 257/E29.164; 257/E21.158

(57) ABSTRACT

A semiconductor device has a substrate, an insulator, an yttrium oxide film, a ferroelectric film (STN film), and an upper electrode.

This application is based upon and claims the benefit of priority from Japanese Patent Application No. 2008-112994, filed on Apr. 23, 2008, the disclosure of which is incorporated herein in its entirety by reference.

### BACKGROUND OF THE INVENTION

1. Field of the Invention

The present invention relates to a ferroelectric film, a semiconductor device with a ferroelectric film, and a method of manufacturing the ferroelectric film and the semiconductor device.

2. Description of the Related Art

As a nonvolatile semiconductor memory, a ferroelectric memory is known, which makes use of spontaneous polarization of a ferroelectric. The ferroelectric memory stores two stable electric polarization states generated by application of an electric field by associating them with “0” and “1”. The ferroelectric memory is advantageous for its lower power consumption and higher operation speed than other nonvolatile memories.

A specific example of the ferroelectric memory comprises a ferroelectric film formed in a capacitor portion. Among field-effect transistor (FET) type ferroelectric memories, one called as “MFIS-FET” has a gate insulating film, the ferroelectric film, and an upper conductive film laminated in this order on a channel forming region of a silicon semiconductor substrate. Another type which is called as “MFMIS-FET” has the gate insulating film, a lower conductive film, the ferroelectric film, and the upper conductive film laminated in this order on the channel forming region of the silicon semiconductor substrate.

As a material for the above-mentioned ferroelectric film, Pb(Zr₁₋ₓTiₓ)O₃ (0≦x≦1) (PZT), SrBi₂Ta₂O₉ (SBT), or the like is conventionally used, but in recent years, attention is given to Sr₂(Ta₁₋ₓNbₓ)₂O₇ (0≦x≦1) (STN) which has a relatively low relative dielectric constant and is hard to be deteriorated in the hydrogen atmosphere.

At present, an STN ferroelectric film is formed, as described in JP-A-10-326872 (Patent Document 1), by a sol-gel process in which a precursor solution of a ferroelectric material is applied and dried to remove organic composition, and then heated to be crystallized. STN is formed of Ta and Nb which have high ionization energy, and hence extremely high energy is necessary for the oxidation of Ta and Nb atoms. The reasons that the above-mentioned sol-gel process is adopted are that an oxygen component is contained in the precursor from the first and hence relatively small amount of oxidation energy is required and that an STN film composition is easily matched.

On the other hand, a ferroelectric film formed by the sol-gel process is rather thick and low in coercive field to be used in a memory. This is why sputtering as described in JP-A-2004-265915 (Patent Document 2) is employed in some cases as a method of forming an STN ferroelectric film.

When sputtering is employed, a ferroelectric film is formed first on a surface of a base by a sputtering process then heated and subjected to radical oxidation, to thereby obtain STN. In either method, the crystallization of STN requires generating STN on a base that is a crystalline substance.

This is because STN crystallizes following the lattice information (lattice constant and other relevant information) of the crystalline substance that serves as the base.

Therefore, an element Pt comprising a lattice constant close to that of STN has conventionally been used as a material of the base as described in, for example, Ichiro Takahashi, “A Research on Techniques of Forming a Ferroelectric STN Thin Film and Its Application to Devices (Summary of Thesis (DR) and Summary of Examination Result)”, Tohoku University, Dec. 15, 2006, p. 390-394 (Non-Patent Document 1).

Pt, however, is not an oxide and raises a problem in that the loss of oxygen from STN during the crystallization of STN creates an oxygen-deficient crystal phase.

Alternative material for the base has been proposed in which IrO₂ is used as a material that comprises lattice information approximate to that of STN and that contains oxygen (Non-Patent Document 1, Patent Document 2).

A structure using IrO₂ as described in Patent Document 2 is a useful structure in terms of accelerating the crystallization of STN while preventing oxygen deficiency.

A drawback is that the grain size of the crystallized STN in the above-mentioned structure is as large as 1 μm or more and is not suitable for use as a semiconductor memory.

Further, the coercive field of the obtained STN is on the order of several tens V/cm, which makes the above-mentioned structure impractical as a semiconductor memory in terms of stable operation.

The above-mentioned structure is also impractical with respect to the cohesiveness between STN and the base.

### SUMMARY OF THE INVENTION

The object of the present invention is to provide a ferroelectric film that enables a device to operate stably and that adheres very closely to a base.

In one aspect of the invention, there is provided a ferroelectric film, comprising as a film material a ferroelectric material containing Sr, Ta, and Nb as its main components, the ferroelectric film being formed on a base that contains yttrium oxide.

In another aspect of the invention, there is provided a method of manufacturing a ferroelectric film, comprising: forming a ferroelectric film containing Sr, Ta, and Nb as its main components on a substrate that contains yttrium oxide.

In still another aspect of the invention, there is provided a semiconductor device, comprising: a ferroelectric film that is formed from a ferroelectric material containing Sr, Ta, and Nb as its main components, on a base film that contains yttrium oxide; and a conductive electrode placed directly on or indirectly above the ferroelectric film.

In further aspect of the invention, there is provided a method of manufacturing a semiconductor device, comprising: forming a ferroelectric film containing Sr, Ta, and Nb as its main components on a base film that contains yttrium oxide.

In still further aspect of the invention, there is provided a ferroelectric device, comprising: a base that contains yttrium oxide; and a ferroelectric film formed on the base from a ferroelectric material containing Sr, Ta, and Nb as its main components.

The present invention can provide a ferroelectric film that enables a device to operate stably and that adheres very closely to a base, as well as a semiconductor device using the ferroelectric film, methods of manufacturing the ferroelectric film and the semiconductor device, and a practical ferroelectric device using the ferroelectric film.

### BRIEF DESCRIPTION OF THE DRAWINGS

FIG. 1 is a cross sectional view of a semiconductor device according to a first embodiment of the present invention;

FIG. 2 shows a sputtering apparatus, with a processing container, a casing, an electrode, a target, and a protective member illustrated in a cross sectional view;

FIG. 3 shows an apparatus for radical-oxidation by plasma, with a processing container, a dielectric window, an antenna member, and a shutter illustrated in a cross sectional view;

FIG. 4 shows an annealing apparatus (furnace), with a casing, a flange, and a heater illustrated in a cross sectional view;

FIG. 5 is a cross sectional view of the annealing apparatus (furnace) of FIG. 3 viewed from the front, with a substrate-to-be-processed and a mounting table illustrated in a side view;

FIG. 6 is a cross sectional view of a substrate-to-be-processed according to the first embodiment;

FIG. 7 is a cross sectional view of the substrate-to-be-processed where a ferroelectric film (STN film) has been formed on the yttrium oxide film according to the first embodiment;

FIG. 8 is a cross sectional view of the substrate-to-be-processed where oxygen radicals have been introduced into the ferroelectric film (STN film) according to the first embodiment;

FIG. 9 is a view illustrating a modified example of FIG. 8;

FIG. 10 is an electron microscopic picture of the ferroelectric film (STN film) that is formed on the yttrium oxide film;

FIG. 11 is a diagram illustrating results of an X-ray diffraction (XRD) analysis on the ferroelectric film (STN film) that is formed on the yttrium oxide film according to the first embodiment;

FIG. 12 is a diagram illustrating CV (Capacitance Voltage) characteristics of the ferroelectric film (STN film) that is formed on the yttrium oxide film according to the first embodiment;

FIG. 13 is a cross sectional view of a ferroelectric memory:

FIG. 14 is a cross sectional view of a semiconductor device according to a second embodiment of the present invention;

FIG. 15 is a cross sectional view of a substrate-to-be-processed that is obtained by forming an SiN film on a substrate according to the second embodiment; and

FIG. 16 is a cross sectional view of the substrate-to-be-processed where the SiN film has been formed on the substrate and an yttrium oxide film has been formed on the SiN film according to the second embodiment.

### DESCRIPTION OF THE EXEMPLARY EMBODIMENTS

Embodiments of the present invention are described below in detail with reference to the drawings.

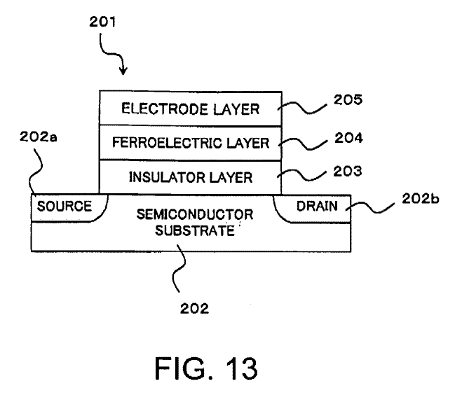

First, the structure of a ferroelectric memory is outlined with reference to FIG. 13.

As illustrated in FIG. 13, a ferroelectric memory 201 (field-effect transistor type ferroelectric memory) is structured to comprise, for example, a semiconductor substrate 202, an insulator layer 203, which is formed on the semiconductor substrate 202; a ferroelectric layer 204, which is formed on the insulator layer 203, and an electrode layer 205, which is formed on the ferroelectric layer 204.

A source region 202a is formed at one end of the insulator layer 203 on a surface of the semiconductor substrate 202, and a drain region 202b is formed at the other end of the insulator layer 203.

Next, the operation of the ferroelectric memory is described briefly.

The ferroelectric layer 204 is polarized by, for example, applying a positive or negative voltage of a certain level or higher to the electrode layer 205, and the resultant polarized state is maintained even after the voltage is removed.

These two different polarization directions are regarded respectively as information “1” and information “0”, whereby the ferroelectric memory 201 is used as a memory.

To read information out of the ferroelectric memory 201, whether stored information is “1” or “0” is determined from whether or not applying a read voltage to the electrode layer 205 causes a drain current to flow between the source region 202a and the drain region 202b.

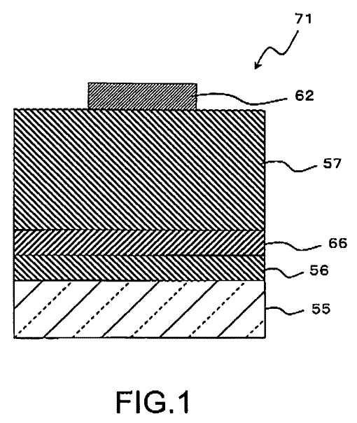

Described next with reference to FIG. 1 is the structure of a semiconductor device 71 according to the present invention which can be used as the ferroelectric memory 201.

As illustrated in FIG. 1, the semiconductor device 71 comprises a semiconductor substrate 55, which is made of Si or the like, an insulator 56, which is provided on the substrate 55, an yttrium oxide film 66, which is provided on the insulator 56, a ferroelectric film (STN film) 57, which is provided on the yttrium oxide film 66, and an upper electrode 62 (conductive electrode), which is provided on the ferroelectric film (STN film) 57.

The upper electrode 62 can be placed directly on or indirectly above the ferroelectric film (STN film) 57.

The components between the electrode 62 and the substrate 55 constitute a ferroelectric capacitor.

Specifically, the substrate 55, which is a semiconductor substrate such as Si, may be an insulating film such as a silicon oxide film, a metal oxide film, or a conductive film.

The insulator 56 is made of an insulating material such as silicon oxide (SiO₂).

The yttrium oxide film 66 is a film that comprises crystals of yttrium oxide (Y₂O₃), and serves as a base when the ferroelectric film (STN film) 57 is crystallized.

Advantages of choosing yttrium oxide as the material of the base film are that yttrium oxide contains oxygen and that the lattice information of yttrium oxide is approximate to that of crystals of the ferroelectric film (STN film) 57.

Further, the ferroelectric film (STN film) 57 adheres more closely to the yttrium oxide film 66 than to an IrO₂ film.

For those reasons, crystallizing STN on the yttrium oxide film 66 gives the ferroelectric film (STN film) 57 a coercive field of 200 kV/cm or more while avoiding oxygen deficiency (details thereof are described later).

The resultant ferroelectric film (STN film) 57 also comprises as fine a crystal grain size as 100 nm, or smaller.

Further, yttrium oxide is less expensive than IrO₂ or Pt, which makes yttrium oxide advantageous in terms of cost as well.

The material of the ferroelectric film (STN film) 57 is one containing Sr, Ta, and Nb. The specific composition of the ferroelectric film (STN film) 57 is, for example, Sr₂(Ta₁₋ₓNbₓ)₂O₇ (0≦x≦1) (STN).

The upper electrode 62 can be any conductor, for example, Al.

The semiconductor device 71 can be used as the ferroelectric memory 201.

In this case, the substrate 55 corresponds to the semiconductor substrate 202 of the ferroelectric memory 201, and a gate insulating film (insulator 56) such as a silicon oxide (SiO₂) film is formed as the insulator layer 203 on a channel region of the semiconductor substrate 202. The yttrium oxide film 66 and the ferroelectric film (STN film) 57 as the ferroelectric layer 204 are then formed on the insulator 56, and the upper electrode 62 is provided as the electrode layer 205. In addition, the upper electrode 62 works as a gate of the field effect transistor and the ferroelectric film (STN film) 57 works as a part of a gate insulating film (insulator 56)

The semiconductor device 71, when used as the ferroelectric memory 201, can comprise a 1Tr structure, a 1T-1C structure, a 2T-2C structure, a 1T-2C structure, or other structures.

How the semiconductor device 71 is manufactured is described next.

The semiconductor device 71 according to this embodiment can be manufactured by such methods as sputtering, application (sol-gel process described above), chemical vapor deposition (MOCVD, for example performed in plasma) using an organic metal compound, and a mist process in which an organometallic compound liquid is turned into a mist to be introduced onto the substrate (letting the organometallic compound react in plasma).

The description here takes sputtering as an example.

When sputtering is employed, the semiconductor device 71 is obtained by first forming a ferroelectric film on a surface of a base through a sputtering process (step of forming a ferroelectric film), then subjecting the ferroelectric film to radical oxidation (step of oxidizing the ferroelectric film), and heating the ferroelectric film (step of heating the ferroelectric film),

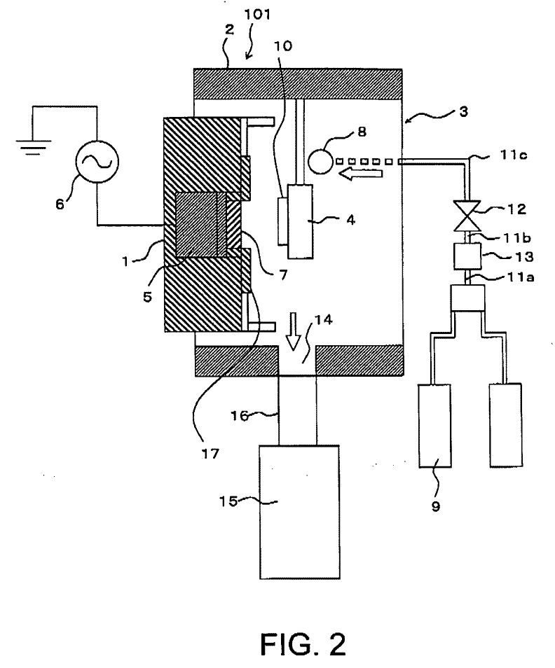

The structure of a sputtering apparatus 101 is described first with reference to FIG. 2.

As illustrated in FIG. 2, the sputtering apparatus 101 comprises, for example, a cylindrical processing container 1, which comprises an open top and a closed bottom, and a hollow, cylindrical casing 2, which is installed such that the top of the processing container 1 can be closed. By closing the top of the processing container 1 with the casing 2, a processing chamber 3 is formed.

A mounting table 4 for bearing a substrate-to-be-processed 10 is provided inside the processing chamber 3. The substrate-to-be-processed 10 is a semiconductor wafer or the like on which a ferroelectric film is formed.

An electrode 5 is embedded in the processing container 1 across from the mounting table 4. The electrode 5 is structured such that a voltage can be applied from a high-frequency power source 6, which is placed outside the processing container 1. The electrode 5 is supported by a protective member 17, and a target 7 is placed on the electrode 5 which faces the mounting table 4. The material of the target 7 is determined by what type of ferroelectric film is to be formed on the substrate-to-be-processed 10.

Further, in a side surface of one end of the processing container 1, a processing gas introducing port 8 is provided, and processing gas supply pipes 11a, 11b, and 11c which lead to a processing gas supply source 9 are connected to the processing gas introducing port 8. A valve 12 and a mass flow controller 13 are provided to the processing gas supply pipes 11a, 11b, and 11c, and the processing gas supply pipe 11c is connected through a wall of the processing container 1 to the processing gas introducing port 8 of the processing chamber 3. Thus, processing gas at a predetermined pressure can be supplied into the processing chamber 3. The processing gas supply source 9 in this embodiment is connected to sources that separately supply rare gas such as Ar gas, Kr gas, and Xe gas, and oxygen gas as the processing gas.

In a side surface of the other end of the processing container 1 facing the above-mentioned processing gas introducing port 8, an exhaust port 14 to exhaust the processing chamber 3 is provided. An exhaust pipe 16 which leads to an exhauster such as a vacuum pump 15 is connected to the exhaust port 14. The pressure in the processing chamber 3, for example, can be reduced to a predetermined pressure by the exhaust from the exhaust port 14.

In the spattering device 101 thus structured, the processing gas supplied into the processing chamber 3 is turned into plasma by the high-frequency power source of the electrode, and rare gas ions are produced. By maintaining the potential of the electrode 5 at a negative potential, positively charged rare gas ions fly toward the target 7 side and collide therewith. By this collision, target species jump out of the target 7. The protective member 17 formed of the same component material as that of the target 7 is attached to a portion with which the rare gas ions may collide, for example, a periphery of the target 7 (at least a portion of an inner surface around the target 7). Thus, even if the rare gas ions erroneously collide with the periphery of the target 7, impurities other than the target species never jump out of the collision portion.

When the processing gas is turned into plasma, oxygen radicals are produced in the processing chamber 3. The target species which have jumped out of the target 7 are oxidized by the oxygen radicals and deposited on the surface of a substrate-to-be-processed 10. A portion exposed to the oxygen radicals in the processing chamber 3 is provided with a quartz film. By the quartz film, the disappearance of the oxygen radicals is inhibited, and the target species in the processing chamber 3 are oxidized.

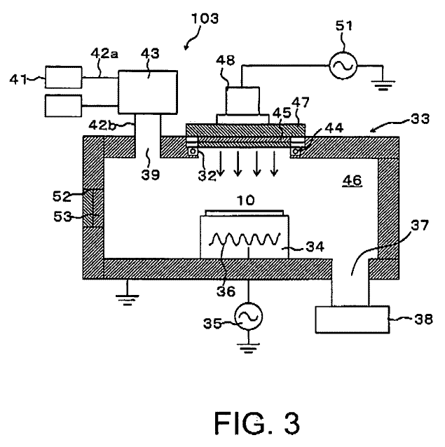

Described next with reference to FIG. 3 is a plasma process apparatus for introducing oxygen into a ferroelectric film with the use of oxygen radicals.

FIG. 3 schematically illustrates a cross sectional view of a plasma process apparatus 103. The plasma process apparatus 103 comprises a substantially cylindrical processing container 33, which comprises an opening 32 in its ceiling. The processing container 33 is grounded. A susceptor 34 on which the substrate-to-be-processed 10 is set is installed on the bottom of the processing container 33. The susceptor 34 comprises a heater 36 inside. An AC power source 35 placed outside the processing container 33 supplies a current with which the heater 36 generates heat, thereby heating the substrate-to-be-processed 10 on the susceptor 34 up to, for example, 500° C. or so.

An exhaust port 37 which communicates with an exhauster 38 such as a turbomolecular pump to exhaust the interior of the processing chamber 33 of gas is provided in the bottom of the processing container 33. A supply port 39 is provided in the ceiling of the processing container 33 which is across the susceptor 34 from the exhaust port 37. Supply pipes 42a and 42b leading to a processing gas supply source 41 are connected to the supply port 39 via a mass flow controller 43. The processing gas supply source 41 in this embodiment is connected to a source for supplying oxygen gas and a source for supplying krypton (Kr) gas, which is rare gas. Gas supplied from the supply port 39 into the processing container 33 passes through the substrate-to-be-processed 10 on the susceptor 34, and is discharged from the exhaust port 37. Krypton gas may be replaced with another rare gas.

A dielectric window 45 made of, for example, quartz glass is installed in the opening 32 of the processing container 33 via an O ring 44 or other types of sealing member that ensures the air-tightness. The dielectric window 45 closes up the processing container 33, thereby creating a processing space 46 inside the processing container 33.

An antenna member 47 is placed above the dielectric window 45. A coaxial waveguide 48 is connected to the top of the antenna member 47. The coaxial waveguide 48 is connected to a microwave feeder 51, which is placed outside the processing container 33. The microwave feeder 51 generates microwaves comprising a frequency of, for example, 2.45 GHz. The microwaves propagate through the coaxial waveguide 48 to the antenna member 47, and are emitted into the processing space 46 through the dielectric window 45. A shutter 53 is provided in a side of the processing container 33 in order to open and close a carry-in/out port 52 through which the substrate-to-be-processed 10 is loaded into the processing container 33.

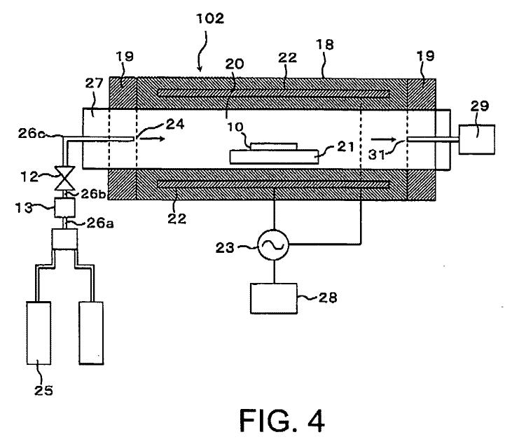

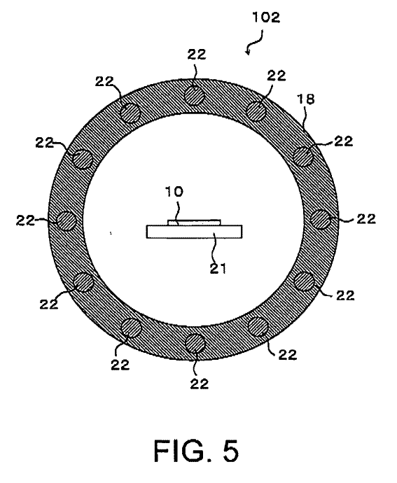

The structure of an annealing apparatus (furnace) 102 as a heating measure is described next with reference to FIGS. 4 and 5.

The annealing apparatus (furnace) 102 comprises, for example, a substantially cylindrical casing 18 comprising an axis running in the horizontal direction as illustrated in FIG. 4. A flange 19 closes each side surface of the casing 18 in the axial direction (each end of the horizontal casing 18), thereby creating a closed processing chamber 20 within the casing 18. A mounting plate 21 on which the substrate-to-be-processed 10 is set is provided in the middle part of the interior of the casing 18.

A cylindrical part (wall) which constitutes a side surface of the casing 18 in the radial direction is formed thick and, as illustrated in FIG. 5, heaters 22 are installed along the entire circumference of the cylindrical wall in order to heat the cylindrical wall uniformly. The substrate-to-be-processed 10 on the mounting plate 21 is thus heated from 360-degree directions evenly. The heaters 22 are connected to a power source 23, which is set outside the casing 18, and use power supplied from the power source 23 to generate heat. The power source 23 is controlled by, for example, a temperature controller 28, which controls the heater temperature by varying the power output of the power source 23. For instance, the mounting plate 21 is provided with a thermocouple as a temperature sensor, and the temperature read by the thermocouple is output to the temperature controller. The temperature controller adjusts the heater temperature based on the temperature reading. What is denoted by reference numeral 27 is a quartz tube.

A processing gas introducing port 24 is opened at one end of the casing 18. Processing gas supply pipes 26a, 26b, and 26c leading to a processing gas supply source 25 are connected to the processing gas introducing port 24. The processing gas supply pipes 26a, 26b, and 26c are provided with a valve 12 and a mass flow controller 13, whereby gas comprising a given pressure is supplied into the processing chamber 20.

The processing gas supply source 25 in this embodiment is connected to sources that separately supply oxygen gas and argon gas as processing gas. Argon gas may be replaced with nitrogen gas.

An exhaust port 31 is provided at the other end of the casing 18, across from the processing gas introducing port 24. The exhaust port 31 communicates with an exhauster 29, which is set outside the casing 18, to exhaust the atmosphere inside the processing chamber 20.

The sputtering apparatus 101 illustrated in FIG. 2, the plasma process apparatus 103 illustrated in FIG. 3, and the annealing apparatus 102 illustrated in FIGS. 4 and 5 comprise the structures described above. Now, a method of manufacturing the ferroelectric film 57 (STN film) according to an embodiment of the present invention is described taking as an example a case of manufacturing the semiconductor device 71 as the ferroelectric memory 201.

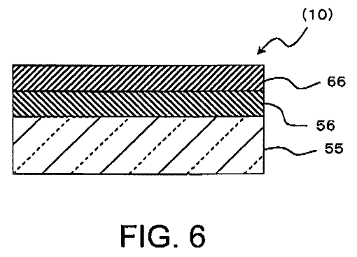

First, as illustrated in FIG. 6, the substrate-to-be-processed 10 is prepared by forming the insulator 56 and the yttrium oxide film 66 on the substrate 55, which is a silicon wafer. The yttrium oxide film 66 can be formed by, for example, sputtering in an oxidizing atmosphere, sputtering in an inert gas atmosphere, sputtering in an oxidizing atmosphere, using a sol-gel process, and oxidizing an yttrium oxide film with oxygen radicals. The prepared substrate is transported to the sputtering apparatus 101 and fixed onto the mounting table 4 as illustrated in FIG. 2. Once the substrate-to be-processed 10 is held to the mounting table 4, the processing chamber 3 is exhausted of gas through the exhaust port 14 so that the pressure in the processing chamber 3 is reduced to, for example, about 10⁻⁷ Pa. Argon gas and oxygen gas are supplied from the processing gas introducing port 8 to fill the processing chamber 3 with argon gas and oxygen gas. The pressure in the processing chamber 3 at this point is, for example, about 4 Pa.

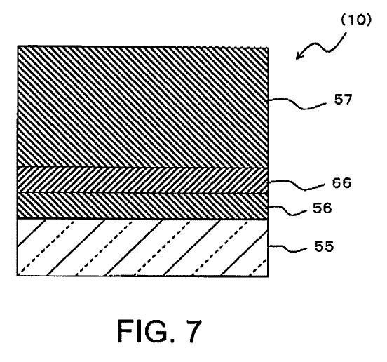

Subsequently, a high-frequency voltage comprising a negative potential is applied to the electrode 5, whereby the gas in the processing chamber 3 is turned into plasma and argon is turned into argon ions by the high-frequency voltage. The argon ions are drawn toward the negative potential electrode 5 and collide with a target 7 at high speed. Upon collision between the argon ions and the target 7, target species jump out of the target 7 to be oxidized with oxygen radicals, which are generated from oxygen gas in plasma. The ferroelectric film (STN film) 57 is thus formed on the yttrium oxide film 66 as illustrated in FIG. 7.

The deposition of STN for forming the ferroelectric film (STN film) 57 is continued for a given period of time, and then the application of the high-frequency voltage is stopped to end the sputtering process in the sputtering apparatus.

After the ferroelectric film (STN film) 57 is formed, the substrate-to-be-processed 10 is brought out of the sputtering apparatus 101 and transported to the plasma process apparatus 103.

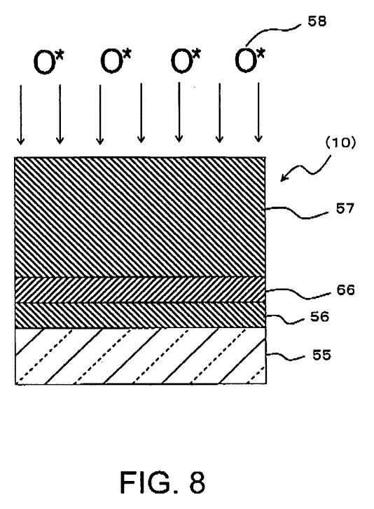

In the plasma process apparatus 103, the substrate-to-be-processed 10 is loaded thereinto thorough the carry-in/out port 52, and as illustrated in FIG. 3, mounted on the susceptor 34 which is maintained, for example, at 400° C. Subsequently, a mixed gas of the oxygen gas and the krypton gas is supplied into the processing space from the supply port 39, and a mixed gas atmosphere is substituted in the processing space. Gas in the processing space is exhausted from the exhaust pipe 37, and the pressure in the processing space is reduced to a predetermined pressure, for example, approximately 133 Pa. Further, a microwave is generated by the microwave feeder 51, and this microwave is propagated to the antenna member 47. Then, the mixed gas in the processing space is turned into plasma by the microwave, and by oxygen radicals 58 thereby produced in the processing space, oxygen is introduced into the ferroelectric film (STN film) 57 as illustrated in FIG. 8. Note that, at this time, a small amount of krypton component is also introduced into the ferroelectric film (STN film) 57.

When the oxygen is introduced into the ferroelectric film (STN film) 57 by the oxygen radicals 58 for a predetermined time, the radiation of the microwave from the antenna member 47 is stopped, and the substrate-to-be-processed 10 is brought out of the plasma process apparatus 103.

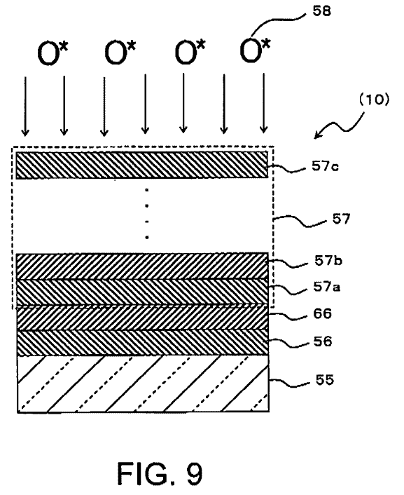

The substrate-to-be-processed 10 brought out of the plasma process apparatus 103 may be transported back to the sputtering apparatus 101 to receive the sputtering process and the plasma process repeatedly, whereby the ferroelectric film (STN film) 57 may be formed in a plurality of layers 57a, 57b. . . and 57c as illustrated in FIG. 9.

In this case, the total thickness of the ferroelectric films (STN films) 57a, 57b. . . , and 57c is, for example, 1 nm or more and 10 nm or less.

After the sputtering process is ended, the substrate-to-be-processed 10 is transported to the annealing apparatus 102 to be set on the mounting plate 21 comprising a temperature that has been raised to, for example, 900° C. by the heaters 22 as illustrated in FIGS. 4 and 5. Oxygen gas or argon gas is introduced into the processing chamber 20 from the processing gas introducing port 24 and, at the same time, the processing chamber 20 is exhausted of gas through the exhaust port 31. In this manner, an air current that flows in the axial direction is created in the processing chamber 20, thereby substituting the existing atmosphere in the processing chamber 20 with an atmosphere of oxygen gas and argon gas while keeping purging the processing chamber 20. The substrate-to-be-processed 10 set on the mounting plate 21 which is maintained at 900° C. is heated and the ferroelectric film (STN film) 57 is crystallized through oxidation. Once the ferroelectric film (STN film) 57 is crystallized, the substrate-to-be-processed 10 is taken out of the annealing apparatus 102 and the annealing process is ended.

Upon completion of the annealing process, an upper conductive film is formed as the upper electrode 62 on the ferroelectric film (STN film) 57 as illustrated in FIG. 1. The upper conductive film is formed by, for example, the above-mentioned sputtering process.

If Kr and Xe which comprise large collision cross sections are used as gas species to form the upper conductive film, damage to the ferroelectric film (STN film) 57 is small enough to make a recovery annealing unnecessary.

In the case where the upper electrode 62 is formed by sputtering and, for example, Kr and Xe, which are rare gas, or Kr, Xe, and oxygen are used as feed gas, the underlying ferroelectric film (STN film) 57 is less damaged due to the fact that the collision cross section of Xe is larger than that of Ar, and therefore the recovery annealing which usually needs to be performed can be omitted.

The semiconductor device 71 illustrated in FIG. 1 is manufactured through the above-mentioned method. It is preferred that the above-mentioned method is performed without exposing the semiconductor device 71 to outside air during transition from a preceding step.

Thus, according to a first embodiment of the present invention, the semiconductor device 71 comprises the substrate 55, the insulator 56, the yttrium oxide film 66, the ferroelectric film (STN film) 57, and the upper electrode 62, with the ferroelectric film (STN film) 57 placed on the yttrium oxide film 66, which serves as a base.

This gives the ferroelectric film (STN film) 57 a coercive field of 200 kV/cm or more, a fine crystal grain size, and an excellent adhesion to the base, while preventing oxygen deficiency.

Further, the semiconductor device 71 structured to place the ferroelectric film (STN film) 57 on the yttrium oxide film 66 can be more reduced in size than in prior art and operate stably, and is low-cost.

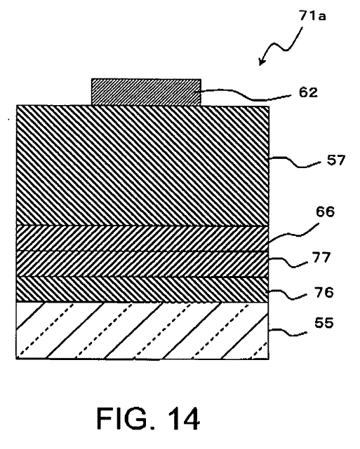

A semiconductor device 71a according to a second embodiment of the present invention is described next with reference to FIGS. 14 to 16.

The semiconductor device 71a according to the second embodiment is obtained by adding a silicon nitride (SiN) film 76 to the semiconductor device 71 of the first embodiment.

First, the schematic structure of the semiconductor device 71a is described with reference to FIG. 14.

As illustrated in FIG. 14, the semiconductor device 71a comprises the SiN film 76 provided between an SiO₂ film 77, which is an insulator, and the substrate 55.

A semiconductor device according to the present invention thus may comprise the SiN film 76 between the SiO₂ film 77 and the substrate 55 and, when structured as this, can be increased in dielectric constant of the gate insulator.

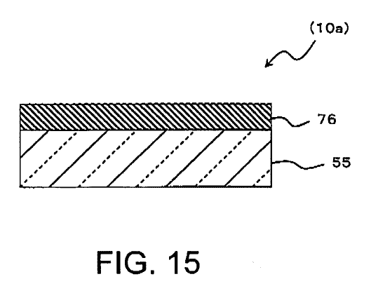

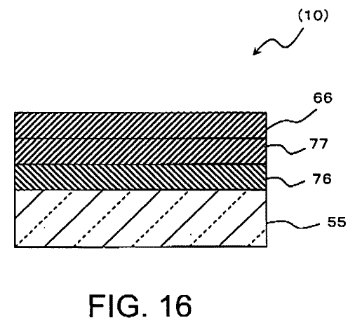

A method of manufacturing the semiconductor device 71a is described next with reference to FIGS. 15 and 16.

An Si substrate is prepared as the substrate 55 first and, as illustrated in FIG. 15, a surface of the substrate 55 is nitrided to form the SiN film 76.

There is no particular nitriding method to be employed. To give an example, the nitriding can be accomplished through a plasma process.

The yttrium oxide film 66 is formed on the surface of the substrate 55 that has been treated by nitriding.

The yttrium oxide film 66 is formed by one of the sputtering of yttrium in an oxidizing atmosphere, the sputtering of yttrium oxide in an inert gas atmosphere, the sputtering of yttrium oxide in an oxidizing atmosphere, and employing the sol-gel process. In any case, the formed yttrium oxide film is oxidized preferably with oxygen radicals. Here, the sputtering of yttrium in an oxidizing atmosphere is employed. Sputtering is performed in an oxidizing atmosphere, and hence a surface of the SiN film 76 is oxidized and forms the SiO₂ film 77 during the formation of the yttrium oxide film 66 and, as illustrated in FIG. 16, it is on the SiO₂ film 77 that the yttrium oxide film 66 is formed.

The SiN film 76 is thus provided between the SiO₂ film 77 and the substrate 55.

The formation of the ferroelectric film (STN film) 57 is not limited to a particular method, and any of the sol-gel process, sputtering, and chemical vapor deposition using an organic metal compound may be employed.

The ferroelectric film (STN film) 57 and the upper electrode 62 here are formed on the yttrium oxide film 66 the same way as in the first embodiment, and the description thereof is omitted.

Thus, according to the second embodiment, the semiconductor device 71a comprises the substrate 55, the SiN film 76, the SiO₂ film 77, the yttrium oxide film 66, the ferroelectric film (STN film) 57, and the upper electrode 62, with the ferroelectric film (STN film) 57 placed on the yttrium oxide film 66, which serves as a base.

The second embodiment therefore comprises the same effects as the first embodiment.

The semiconductor device 71a according to the second embodiment comprises the SiN film 76 provided between the SiO₂ film 77 and the substrate 55.

This improves the characteristics of the semiconductor device 71a as a ferroelectric memory even more than those of the semiconductor device 71 of the first embodiment.

### EXAMPLE

Next, the present invention is described in more detail through concrete examples.

### Example 1

An STN film was formed to a thickness of 130 nm on a 6 nm-thick yttrium oxide film with the use of the sputtering apparatus 101, the plasma process apparatus 103, and the annealing apparatus (furnace) 102 illustrated in FIGS. 2 to 5. A surface of the STN film was observed under 100,000 power magnification.

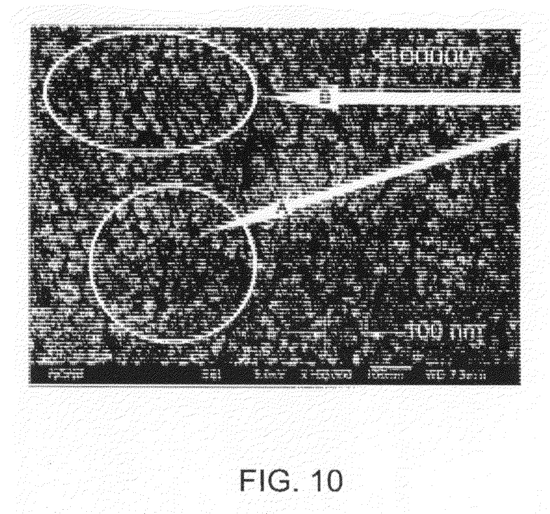

Results of the observation are shown in FIG. 10.

As is clear from FIG. 10, the STN film comprises fine crystals with a crystal grain size of several tens nm (for example, regions indicated by white arrows A and B of FIG. 10), and it was proven that forming an STN film on an yttrium oxide thin film makes crystal grains finer.

### Example 2

An STN film was formed on an yttrium oxide thin film in the same way as in Example 1, with the use of the sputtering apparatus 101, the plasma process apparatus 103, and the annealing apparatus (furnace) 102 illustrated in FIGS. 2 to 5. With an X-ray diffraction (XRD) analyzer, the crystal structure of the STN film was analyzed within a range of 2θ=20° to 60°.

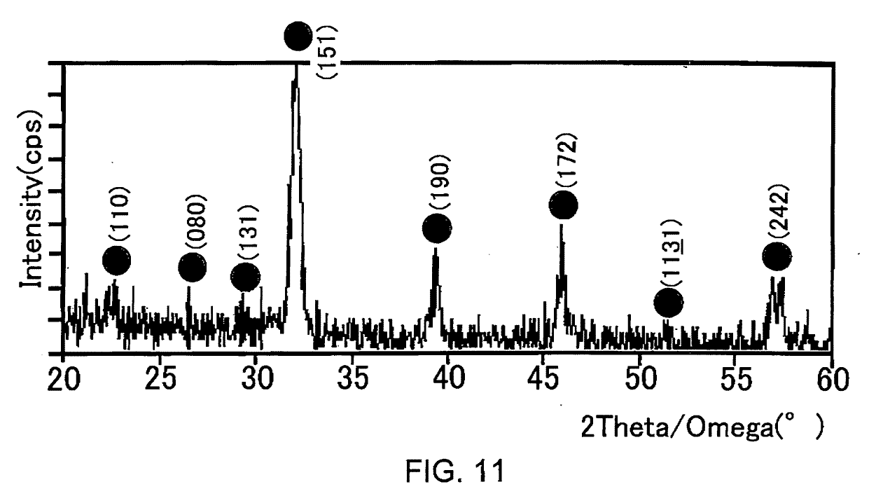

Results are shown in FIG. 11.

As is clear from FIG. 11, perovskite STN (2/2/7) was formed as the STN film on the yttrium oxide thin film.

### Example 3

The semiconductor device 71 illustrated in FIG. 1 was built with the use of the sputtering apparatus 101, the plasma process apparatus 103, and the annealing apparatus (furnace) 102 illustrated in FIGS. 2 to 5. The high-frequency CV characteristics of the semiconductor device 71 were evaluated.

First, a Cz p-Si substrate was prepared as the substrate 55 and a 7 nm-thick SiO₂ film was formed as the insulator 56 on the substrate 55.

Under the same condition as in Example 1, a 6 nm-thick Y₂O₃ film was formed as the yttrium oxide film 66 on the insulator 56, and an STN film with a dielectric constant (STN) of 30 was formed to a thickness of 130 nm as the ferroelectric film (STN film) 57.

As the upper electrode 62, an Al film was formed by sputtering.

The high-frequency CV characteristics were evaluated under conditions where the capacitor area of the ferroelectric film (STN film) 57 is 4.9×10⁻⁴ cm² and the frequency of the applied voltage is 1 MHz.

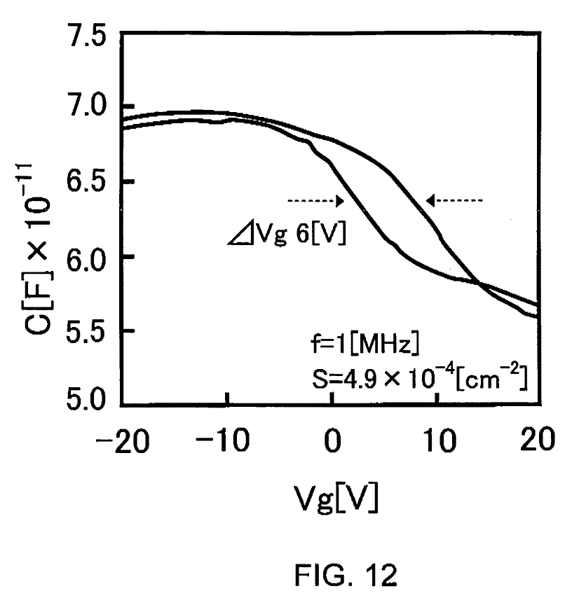

Results are shown in FIG. 12.

As is clear from FIG. 12, the CV characteristics of the semiconductor device 71 form a counter-clockwise hysteresis curve indicating ferroelectricity, and the coercive field of the ferroelectric film (STN film) 57 was revealed to be astonishingly high at 230 kV/cm.

It was also revealed that a memory window (ΔVg) derived from the ferroelectric film (STN film) 57 is 6 V.

As has been described above, the ferroelectric film and the semiconductor device according to the present invention, the methods of manufacturing the ferroelectric film and the semiconductor device according to the present invention, and the ferroelectric device according to the present invention are applicable to the manufacture of electronic parts and electronic apparatuses such as a ferroelectric memory device.

What is claimed is:

1. A semiconductor device, comprising:
a ferroelectric film that is formed from a ferroelectric material containing Sr, Ta, and Nb as its main components, on a base film that contains yttrium oxide; and
a conductive electrode is placed directly on or indirectly above the ferroelectric film.

2. A semiconductor device according to claim 1, wherein the ferroelectric film comprises a coercive field of 200 kV/cm or more.

3. A semiconductor device according to claim 1, wherein the ferroelectric film comprises a crystal grain size of 100 nm or less.

4. A semiconductor device according to claim 1, wherein the base film contains Y₂O₃.

5. A semiconductor device according to claim 1, wherein the ferroelectric material is a material expressed by the following composition formula:
Sr₂(Ta₂₋ₓNbₓ)₂O₇ (0≦x≦1),

6. A semiconductor device according to claim 1, wherein the ferroelectric film is introduced with an oxygen component by oxygen radicals.

7. A semiconductor device according to claim 6, wherein the ferroelectric film contains a rare gas element.

8. A semiconductor device according to claim 7, wherein the rare gas element comprises at least one of elements of Kr and Xe.

9. A semiconductor device according to claim 1, wherein the conductive electrode works as a gate of a field effect transistor and the ferroelectric film works as part of a gate insulating film of the transistor.

10. A semiconductor device according to claim 9, wherein the gate insulating film comprises the base film and an insulating film, which is provided between a semiconductor substrate and the base film.

11. A semiconductor device according to claim 1, further comprising an Si substrate and an insulating film formed on the Si substrate,
wherein the base film is formed on the insulating film.

12. A semiconductor device according to claim 11, wherein the insulating film comprises a silicon oxide film.

13. A semiconductor device according to claim 11, wherein the insulating film comprises a silicon nitride film.

14. A semiconductor device according to claim 1, further comprising an insulating film that comprises a silicon nitride film formed on a silicon substrate and a silicon oxide film formed on the silicon nitride film,
wherein the base film is formed on the insulating film.

15. A semiconductor device according to claim 1, being used as a ferroelectric memory.

16. A method of manufacturing a semiconductor device comprising: the step (a) of forming a ferroelectric film containing Sr, Ta, and Nb as its main components on a base film that contains yttrium oxide.

17. A method of manufacturing a semiconductor device according to claim 16, further comprising:
the step (b) of oxidizing the ferroelectric film with oxygen radicals; and
the step (c) of heating the ferroelectric film.

18. A method of manufacturing a semiconductor device according to claim 16, further comprising:
the step (d) of forming an insulating film on a semiconductor substrate; and
the step (e) of forming the base film on the insulating film.

19. A method of manufacturing a semiconductor device according to claim 18, wherein the step (d) comprises at least one of forming a nitride film by nitriding a surface of the semiconductor substrate and forming an oxide film.

20. A method of manufacturing a semiconductor device according to claim 18, wherein the step (e) comprises at least one of forming an yttrium film by sputtering in an oxidizing atmosphere, forming an yttrium oxide film by sputtering in an inert gas atmosphere, forming an yttrium oxide film by sputtering in an oxidizing atmosphere, forming an yttrium oxide film by a sol-gel process, and oxidizing an yttrium oxide film with oxygen radicals.

21. A method of manufacturing a semiconductor device according to claim 16, wherein the step (a) comprises at least one of forming the ferroelectric film by a sol-gel process, forming the ferroelectric film by sputtering, and forming the ferroelectric film by chemical vapor deposition using an organic metal compound.

22. A method of manufacturing a semiconductor device according to claim 18, wherein at least one of the step (a) and the step (e) is performed without exposing the semiconductor device to outside air during transition from a preceding step.

23. A method of manufacturing a semiconductor device according to claim 16, wherein the base film contains Y₂O₃.

24. A method of manufacturing a semiconductor device according to claim 16, wherein, in the step (a), the ferroelectric film is formed in a processing chamber comprising at least a portion of an inner surface around a target, which is formed from the same material that constitutes the target, by letting ions in plasma collide with the target and depositing target atoms, which are generated by the colliding, on the base film,

25. A method of manufacturing a semiconductor device according to claim 17, wherein the oxygen radicals of the step (b) are generated by a plasma process that involves rare gas and oxygen.

26. A method of manufacturing a semiconductor device according to claim 25, wherein the rare gas comprises at least one of Kr gas and Xe gas.

27. A method of manufacturing a semiconductor device according to claim 21, the chemical vapor deposition is performed in plasma.

28. A method of manufacturing a semiconductor device according to claim 16, wherein the ferroelectric film is formed by turning an organometallic compound liquid into a mist, introducing the mist onto a substrate, and letting the organometallic compound react.

29. A method of manufacturing a semiconductor device according to claim 18, wherein the step (d) comprises forming a siabalicon nitride film on a silicon substrate and the step (e) comprises forming a yttrium oxide film on the silicon nitride film in an oxidizing atmosphere.
